(19) United States
(12) Patent Application Publication
(10) Pub. No.: US 2008/0192529 A1
(43) Pub. Date: Aug. 14, 2008

(54) INTEGRATED CIRCUIT HAVING A RESISTIVE MEMORY

(75) Inventors: Heinz HOENIGSCHMID, Poecking (DE); Stefan DIETRICH, Tuerkenfeld (DE); Milena DIMITROVA, Unterhaching (DE); Michael MARKERT, Augsburg (DE)

Correspondence Address: DICKE, BILLIG & CZAJA, FIFTH STREET TOWERS, 100 SOUTH FIFTH STREET, SUITE 2250, MINNEAPOLIS, MN, 55402, US

(73) Assignee: QIMONDA AG, Muenchen (DE)

(21) Appl. No.: 11/673,111

(22) Filed: Feb. 9, 2007

(51) Int. Cl. G11C 11/00

(52) U.S. Cl. 365/148

(57) ABSTRACT

An integrated circuit having a resistive memory including a resistive memory element, a selection device, a conductive line, and a reference electrode is disclosed. In one embodiment, the conductive line is set to a first voltage for establishing a first resistive state of the resistive memory element and to a second voltage, being lower than the first voltage, for establishing a second resistive state of the resistive memory element. The reference electrode is coupled to the resistive memory element and is set to a voltage level being provided between the first voltage and the second voltage.

### BACKGROUND

The invention relates to a resistive memory cell and to a memory device having resistive memory cells. The invention further relates to a method of operating a resistive memory cell.

Demands imposed on large scale integrated electronic circuits are constantly increasing. To ensure the economic success of modern electronic circuits, such as electronic data memories, programmable logic modules, or microprocessors, ongoing development is mainly aimed at structure density, speed, and, an optimization of power consumption.

The latter issue, the optimization of power consumption, has become more and more important, since the advent of mobile handheld applications of powerful integrated devices. In such mobile applications, the available amount of energy is generally limited, and a minimization of the consumed power may be often required. Furthermore, also stationary applications may require a minimization of the consumed power, since the application must meet environment-friendly regulations or the application itself imposes limitations, for example, due to a limited amount of heat which may be safely dissipated from the respective electronic circuitry to a surrounding.

While modern integrated electronic devices include the already mentioned data memories, logic devices, and microprocessors, substantial scientific and industrial research effort is made to develop new concepts for electronic data storage. Conventional electronic data memories, such as the dynamic random access memory (DRAM) or the Flash-RAM, still set too narrow limitations, and are, therefore, discontenting. Hence, it is very desirable to develop reliable alternatives, which, for example, do not require continuous refreshing or do not require high operation voltages.

A prominent example for a modern electronic memory is an electronic data memory with resistive memory cells. These resistive memory cells change their electric resistance by the application of electric signals, while the electric resistance remains stable in the absence of any signal. In this way, such a memory cell may store two or more logic states by a suitable programming of its electric resistance. A binary coded memory cell may, for example, store an information state “0” by assuming a high-resistive state, and an information state “1” by assuming a low-resistive state. Promising concepts for such resistive memory cells include magnetoresistive memory cells (MRAM), phase change memory cells (PCRAM), and conductive bridging memory cells (CBRAM).

In an actual electronic memory device, many memory cells are integrated on a single chip, usually arranged in an array along word lines and, perpendicular thereto, bit lines. A single memory cell may then be addressed via the activation of the respective word line and the respective bit line. At the crossing of the two respective lines a selection transistor is put into a conductive state, such that write or read signals may be led through the cell to a common reference electrode.

Conventional resistive memory cells may include a back gate of the selection transistor to minimize idle currents and to minimize the power consumption of the device. Furthermore, the potential of the addressing lines in conventional memory devices may be drawn above and below a ground potential to achieve a bi-directional current through the resistive memory cell.

For these and other reasons, there is a need for the present invention.

### SUMMARY

One embodiment provides for an integrated circuit having a resistivity changing device. The device includes a resistive element having a first resistive state and a second resistive state; a selection device; and a conductive line. The conductive line is configured to be set to a first voltage for establishing the first resistive state, and a second voltage for establishing the second resistive. A reference coupled to the resistive element, set to a voltage level between the first voltage and the second voltage.

### BRIEF DESCRIPTION OF THE DRAWINGS

The accompanying drawings are included to provide a further understanding of the present invention and are incorporated in and constitute a part of this specification. The drawings illustrate the embodiments of the present invention and together with the description serve to explain the principles of the invention. Other embodiments of the present invention and many of the intended advantages of the present invention will be readily appreciated as they become better understood by reference to the following detailed description. The elements of the drawings are not necessarily to scale relative to each other. Like reference numerals designate corresponding similar parts.

FIG. 1 illustrates a schematic view of a memory cell according to a first embodiment of the present invention.

FIG. 2 illustrates a schematic view of a memory cell according to a second embodiment of the present invention.

FIGS. 3A and 3B illustrate a schematic view of a memory cell according to a third and a fourth embodiment of the present invention.

FIGS. 4A and 4B illustrate a schematic view of a memory cell according to a fifth and a sixth embodiment of the present invention.

FIGS. 5A and 5B illustrate a schematic view of a memory cell according to a seventh and an eighth embodiment of the present invention.

FIG. 6 illustrates a schematic view of an array of resistive memory cells, according to a ninth embodiment of the present invention.

FIG. 7 illustrates a schematic view of a memory device with resistive memory cells, according to a tenth embodiment of the present invention.

FIG. 8 illustrates a schematic cross-sectional view of a memory device with resistive memory cells, according to an eleventh embodiment of the present invention.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

One embodiment provides particular advantages for an improved resistive memory cell, an improved memory device, and an improved method of operating a resistive memory cell.

In another embodiment, a resistive memory cell includes a resistive memory element, the resistive memory element having a first resistive state and a second resistive state; a selection device, a first terminal of the selection device being coupled to a first terminal of the resistive memory element, the selection device having an on-state and an off-state; a conductive line, the conductive line being coupled to a second terminal of the selection device, the conductive line being set to a first voltage, the first voltage establishing the first resistive state of the resistive memory element via the selection device having the on-state, the conductive line being set to a second voltage being lower than the first voltage, the second voltage establishing the second resistive state of the resistive memory element via the selection device having the on-state; and a reference electrode, the reference electrode being coupled to a second terminal of the resistive memory element, the reference electrode being set to a voltage level being provided between the first voltage and the second voltage.

In another embodiment, an integrated circuit includes an array of resistive memory cells, the resistive memory cells having a resistive memory element and a selection device, the resistive memory element having a first resistive state and a second resistive state, a first terminal of the selection device being coupled to a first terminal of the resistive memory element, the selection device having an on-state and an off-state; a bit line being coupled to a second terminal of the selection device, the bit line being set to a first voltage, the first voltage establishing the first resistive state of the resistive memory element via the selection device having the on-state, the bit line being set to a second voltage, the second voltage being lower than the first voltage, the second voltage establishing the second resistive state of the resistive memory element via the selection device having the on-state; and a reference electrode, the reference electrode being coupled to a second terminal of the resistive memory element, the reference electrode being set to a voltage level being provided between the first voltage and the second voltage.

In another embodiment, a method of operating an integrated circuit having a resistive memory cell is provided, the resistive memory cell including: a resistive memory element, the resistive memory element having a first resistive state and a second resistive state; a selection device, a first terminal of the selection device being coupled to a first terminal of the resistive memory element, the selection device having an on-state and an off-state; a conductive line, the conductive line being coupled to a second terminal of the selection device; and a reference electrode, the reference electrode being coupled to a second terminal of the resistive memory element, the method including the following processes: setting the selection device to the on-state; setting the reference electrode to a voltage between a first voltage and a second voltage; setting the conductive line to the first voltage, the first voltage establishing the first resistive state of the resistive memory element; and setting the conductive line to the second voltage, the second voltage being lower than the first voltage and the second voltage establishing the second resistive state of the resistive memory element.

In another embodiment, a resistive memory cell includes a resistive memory element, the resistive memory element having a first resistive state and a second resistive state; a selection device, a first terminal of the selection device being coupled to a first terminal of the resistive memory element, the selection device having an on-state and an off-state; a conductive line, the conductive line being coupled to a second terminal of the selection device, the conductive line being set to a first voltage, the first voltage establishing the first resistive state of the resistive memory element via the selection device having the on-state, the conductive line being set to a second voltage being lower than the first voltage, the second voltage establishing the second resistive state of the resistive memory element via the selection device having the on-state; a reference electrode, the reference electrode being coupled to a second terminal of the resistive memory element; and a second electrode, the second electrode being coupled to a third terminal of the selection device, the second electrode being set to a third voltage during the first resistive state set operation of the resistive memory element and to a fourth voltage during the second resistive state set operation of the resistive memory element.

In another embodiment, an integrated circuit includes an array of resistive memory cells, the resistive memory cells having a resistive memory element and a selection device, the resistive memory element having a first resistive state and a second resistive state, a first terminal of the selection device being coupled to a first terminal of the resistive memory element, the selection transistor having an on-state and an off-state; a bit line being coupled to a second terminal of the selection device, the bit line being set to a first voltage, the first voltage establishing the first resistive state of the resistive memory element via the selection device having the on-state, the bit line being set to a second voltage, the second voltage being lower than the first voltage, the second voltage establishing the second resistive state of the resistive memory element via the selection device having the on-state; a back gate electrode, the back gate electrode being coupled to a third terminal of the selection device, the back gate electrode being set to a third voltage during the first resistive state set operation of the resistive memory element and to a fourth voltage during the second resistive state set operation of the resistive memory element; and a reference electrode, the reference electrode being coupled to a second terminal of the resistive memory element, the reference electrode being set to a voltage level being provided between the first voltage and the second voltage.

In another embodiment, a method of operating an integrated circuit having a resistive memory cell is provided, the resistive memory cell having a resistive memory element, the resistive memory element having a first resistive state and a second resistive state; a selection device, a first terminal of the selection device being coupled to a first terminal of the resistive memory element, the selection device having an on-state and an off-state; a conductive line, the conductive line being coupled to a second terminal of the selection device; a reference electrode, the reference electrode being coupled to a second terminal of the resistive memory element; and a second electrode, the second electrode being coupled to a third terminal of the selection device, the method including the following processes: setting the selection device to the on-state; setting the reference electrode to a voltage between a first voltage and a second voltage; setting the conductive line to the first voltage, the first voltage establishing the first resistive state of the resistive memory element; setting the conductive line to the second voltage, the second voltage being lower than the first voltage and the second voltage establishing the second resistive state of the resistive memory element; setting the second electrode to a third voltage during the first resistive state set operation of the resistive memory element; and setting the second electrode to a fourth voltage during the second resistive state set operation of the resistive memory element.

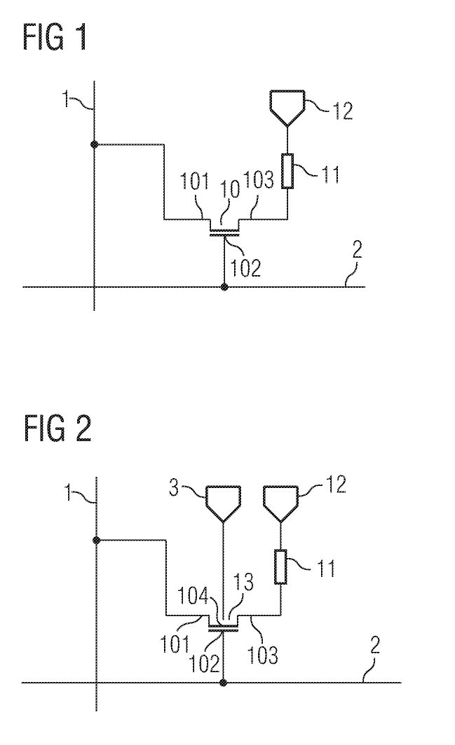

FIG. 1 illustrates a schematic view of a resistive memory cell according to a first embodiment of the present invention. The memory cell includes a selection transistor 10 and a resistive memory element 11. A first terminal 101 of the selection transistor 10, usually also denoted as a source or a drain, is coupled to a first conductive line 1. A second terminal 102, usually also denoted as a gate, of the selection transistor 10 is coupled to a second conductive line 2. The first conductive line 1 may be a bit-line and the second conductive line 2 may be a word-line, such to address the memory cell by a respective setting of the voltages of the first conductive line 1 and the second conductive line 2. A third terminal 103 of the selection transistor 10, usually denoted as the opposite to the first terminal 101, i.e. drain or source, is coupled to a first terminal of the resistive memory element 11. A second terminal of the resistive element 11 is coupled to a reference electrode 12.

The resistive memory element 11 stores a unit of information by assuming at least two distinct and distinguishable resistive states. A low resistive state, wherein the electric resistance of the resistive memory element 11 may be below 10 kΩ, may represent an information state “1”, while a high resistive state, wherein the electric resistance may be above 10 kΩ up to 1 GΩ and above, may represent an information state “0”. The above mentioned threshold resistance may also be well below 10 kΩ or well above 10 kΩ. The resistive memory element 11, as any other resistive memory element described in the present invention, may further represent more than two information states, via assuming more than two distinguishable resistive states. For example, two binary bits may be stored in a single resistive memory element 11, if the resistive memory element 11 assumes four distinguishable resistive states. The selection transistor 10 is usually a field-effect transistor, and may be an NMOS field-effect transistor.

Possible realizations of the resistive memory element 11 include a magnetoresistive memory (MRAM) element, a phase change memory (PC-RAM) element, or a conductive bridging memory (CB-RAM) element.

A suitable material system for conductive bridging memory elements are solid electrolytes. In such materials a conductive path may be formed by the application of electric signals. The switching mechanism is based on the polarity-dependent electrochemical deposition and removal of a metal in a thin solid state electrolyte film. In this concept, an on-state or a low-resistive state is achieved by applying a positive bias at an oxidizeable anode resulting in a redox-reaction, driving ions, for example silver-ions, into a chalcogenide glass, such as germanium selenide. This leads to a formation of metal rich clusters, which form a conductive bridge. The element may be switched back to an off-state or a high-resistive state by applying an opposite voltage, whereby the metal ions are removed. Once a continuous path of ions is formed, this path may short circuit the otherwise high resistive solid electrolyte between two electrodes, hence reducing the effective electric resistance. In this way, two distinct resistive states may be written into such a CB-RAM element, by a bi-directional programming current.

Another example of a modern resistive memory element is a magnetoresistive memory element, such as a spin torque MRAM element. Such an element usually includes a thin free and a thick fixed magnetic layer with an isolating barrier layer in between. The thick fixed layer provides a magnetic material with a magnetic moment of fixed orientation, such that its magnetization is uniform an remains usually unchanged. The thin free layer, however, provides a magnetic material with a magnetic moment of a variable orientation. It may be changed such that the magnetic moment may be aligned parallel or anti-parallel to the magnetic moment of the fixed layer.

The intermediate isolating layer provides a tunneling barrier between the two conductive magnetic layers. In the case of a parallel alignment of the thin and thick films' magnetic orientations, tunneling is enhanced and the element is in a low-resistive state, whereas anti-parallel alignment of the thin and thick films' magnetic orientations results in an attenuated tunneling, which, in turn, corresponds to a high-resistive state of the element. Once currents through the cell do not exceed a threshold current, the magnetic orientation of the free layer remains stable, and the element may reliably hold its resistive state, even without further supplies.

Electrons flowing through the fixed layer are spin polarized in the way that their spins become aligned to the magnetic orientation of the fixed layer. Spin polarized electrons, flowing from the fixed layer to the thin layer may change the magnetization of the free layer such that the thin and thick films' magnetic orientations become aligned parallel. Likewise, electrons which flow the opposite direction, i.e. from the free layer to the fixed layer, get reflected if their spins are aligned anti-parallel to the magnetic moment of the fixed layer. Hence, they may change the magnetization of the free layer such that the thin and thick films' magnetic moments become aligned anti-parallel. An electronic writing current during a writing operation therefore programs either a low-resistive state or a high-resistive state, dependent on the direction of the current. In this way, two distinct resistive states may be written into such an MRAM element, by a bi-directional programming current.

According to one embodiment of the present invention, the second conductive line 2 is set to a voltage such that the selection transistor 10 becomes conductive, i.e. is put to its on-state. A first voltage is applied at the first conductive line 1 to establish a first resistive state of the resistive memory element 11, while a second voltage is applied at the first conductive line 1 to establish a second resistive state of the resistive memory element 11. The voltage at reference electrode 12, i.e. the reference voltage, may be between the first voltage and the second voltage. In this way, the direction of the current through the resistive memory element 11 is reversed by switching the voltage of the first conductive line between the first voltage and the second voltage. In the case of the first conductive line being set to the first voltage, being higher than the second voltage and being higher than the reference voltage, a current flows from the first conductive line 1 through the selection transistor 10 and the resistive memory element 11 to the reference electrode 12. In the case that the first conductive line 1 is set to a second voltage, being lower than the first voltage and the reference voltage, a current flows from the reference electrode 12 through the resistive memory element 11 and the selection transistor 10 to the first conductive line 1. In general, when describing a direction of a current, the direction of a conventional current is assumed here. The actual direction of the flow of charge carriers, such as electrons, may differ from the direction of a corresponding conventional current.

Hence, it is possible, that the electronic current through the resistive memory element 11 is reversed by switching the first conductive line 1 between a first voltage and a second voltage, while keeping the selection transistor 10 in its on-state. The latter is achieved by a respective voltage at the second conductive line 2 to drive the second terminal 102 of the selection transistor 10. Since the reference electrode 12 is tied to a voltage between the first voltage and the second voltage, wherein the second voltage may be as low as a ground potential, for example 0V, the potential of the first conductive line 1 need not to be drawn below the second voltage in order to achieve a bi-directional current. In general, generating a low voltage in an electronic circuit, particularly a voltage below a ground potential, may require additional components and may increase circuit complexity.

According to one embodiment of the present invention, the reference voltage at the reference electrode may be provided between 50 percent and 150 percent of a center voltage, the center voltage being equal to the second voltage plus half the difference between the first voltage and the second voltage. The reference voltage at the reference electrode may also be provided between 75 percent and 125 percent of the center voltage. The reference voltage at the reference electrode may furthermore correspond approximately to the center voltage. For example, the first voltage may correspond to a high-level voltage of 3 volts and the second voltage may correspond to a ground voltage of 0 volts, the center voltage accordingly being 1.5 volts.

A third voltage at the first conductive line 1 may be applied for determining the resistive state of the resistive memory element 11. The difference between the third voltage and the reference voltage does not suffice to substantially alter the resistive state of the memory element 11. Therefore, the element 11 may be read out non-destructively. The memory element 11 may keep the information content even without any signals or voltages. Such a non-volatile memory element 11 keeps the information consequently without an energy supply, in contrast to, for example, a DRAM element, which has to be continuously refreshed in order to keep and maintain a respective information state.

FIG. 2 illustrates a schematic view of a resistive memory cell according to a second embodiment of the present invention. The memory cell includes a selection transistor 13 and a resistive memory element 11. A first terminal 101 of the selection transistor 13 is coupled to a first conductive line 1. A second terminal 102 of the selection transistor 13 is coupled to a second conductive line 2. A third terminal 103 of the second selection transistor 13 is coupled to a first terminal of the resistive terminal element 11. A second terminal of the resistive element 11 is coupled to the reference electrode 12. A fourth terminal 104 of the selection transistor 13 is coupled to a second electrode 3. The second electrode 3 may be realized as an underlying or buried electrode or as a connection to an additional conductive line. As far as possible realizations of the memory element 11 are concerned, it is to be noted that the detailed description in conjunction with FIG. 1 of the resistive memory element 11 of FIG. 1 may also apply to the resistive memory element 11 of FIG. 2.

The second terminal 102 of the selection transistor 13 is coupled to the second conductive line 2, which may represent a word-line. Hence the second terminal 102 of the selection transistor 13 may represent a gate-contact. Accordingly biasing the gate 102 renders the selection transistor 13 conductive and sets it into its on-state. The fourth terminal 104 of the selection transistor 13 may act as a back-gate and allows for further tuning of the conductance of the transistor channel.

The effective voltage at the fourth terminal 104 either broadens the conductive channel or narrows it. In this way, the conductive channel of the transistor 13 may be enhanced or depleted. Even if the voltages at the first terminal 101 and the second terminal 103 are such that a gate-bias at the second terminal 102 via the second conductive line 2 does not suffice to put the transistor 13 into its on-state or off-state, an application of an appropriate voltage at the fourth terminal 104 allows then for a complete opening or closing of the conductive channel.

According to one embodiment of the present invention, the second conductive line 2 is set to a voltage such that the selection transistor 13 becomes conductive during a program operation. During the program operation a first voltage is further applied at the first conductive line 1 to establish a first resistive state of the resistive memory element 11. This first resistive state of the element 11 may correspond to a low-resistive state.

During an erase operation, the second conductive line 2 is set to a voltage such that the selection transistor 13 becomes conductive. During the erase operation a second voltage is further applied at the first conductive line 1 to establish a second resistive state of the resistive memory element 11. This second resistive state of the element 11 may correspond to a high-resistive state.

The voltage at reference electrode 12, i.e. the reference voltage, may be between the first voltage and the second voltage. In this way, the direction of the current through the resistive memory element 11 is reversed by switching the voltage of the first conductive line between the first voltage and the second voltage. In the case of this first conductive line being set to the first voltage, being higher than the second voltage and being higher than the reference voltage, a current flows from the first conductive line 1 through the selection transistor 13 and the resistive memory element 11 to the reference electrode 12. In the case that the first conductive line 1 is set to a second voltage, being lower than the first voltage and the reference voltage, a current flows from the reference electrode 12 through the resistive memory element 11 and the selection transistor 13 to the first conductive line 1.

Hence, it is possible, that the electronic current through the resistive memory element 11 is reversed by switching the first conductive line 1 between a first voltage and a second voltage, while keeping the selection transistor 13 in its on-state by a respective voltage at a second conductive line 2 to drive the second terminal 102 of the selection transistor 13.

A third voltage at the first conductive line 1 may be applied during a read operation for determining the resistive state of the resistive memory element 11. The difference between the third voltage and the reference voltage may not suffice to substantially alter the resistive state of the memory element 11. Therefore, the element 11 may be read out non-destructively.

According to one embodiment of the present invention, the reference voltage at the reference electrode may be provided between 50 percent and 150 percent of a center voltage, the center voltage being equal to the second voltage plus half the difference between the first voltage and the second voltage. The reference voltage at the reference electrode may also be provided between 75 percent and 125 percent of the center voltage. The reference voltage at the reference electrode may furthermore correspond approximately to the center voltage. For example, the first voltage may correspond to a high-level voltage of 3 volts and the second voltage may correspond to a ground voltage of 0 volts, the center voltage accordingly being 1.5 volts.

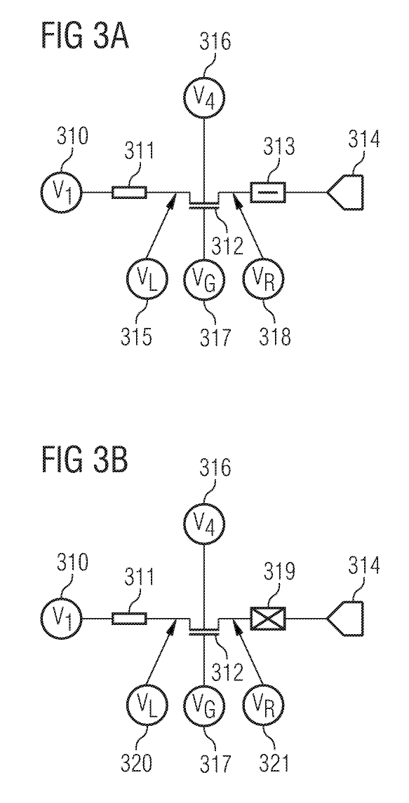

FIG. 3A illustrates a schematic view of a selection transistor 312 with a resistive memory element 313 according to a third embodiment of the present invention. According to this embodiment, the resistive memory element 313, such as the element 11 as described in conjunction with FIG. 1 or 2, is in a low-resistive state. During a program operation, a first voltage V₁ is applied at point 310, whereas a reference voltage, being higher than the first voltage V₁, is applied at the reference electrode 314. According to this embodiment, the first voltage V₁ may be approximately 0 volts, whereas the reference electrode 314 is at a voltage of approximately 1.5 volts.

In order to render the selection transistor 312 conductive, a gate voltage V_{G} is applied at point 317, being approximately 3 volts. There may be an effective resistance 311, for example the resistance of a bit-line, between the point 310 and the point 315 (V_{L}) at the selection transistor 312. The resistance 311 results in a voltage drop |V₁-V_{L}| between the point 310 and the point 315. Furthermore, the selection transistor 312 may also possess an effective resistance, which may result in a voltage drop |V_{L}-V_{R}| between the point 315 and the point 318. In the case of the resistive memory element 313 being in a low-resistive state, for example below 10 kΩ, the resulting voltages may be approximately 0.5 volts for V_{L} and approximately 1 volt for V_{R}.

According to the present invention, a threshold voltage Vₜₕ may be assigned to a selection transistor, such as the selection transistor 312, 412, or 512. The threshold voltage Vₜₕ may be a figure of a characteristic voltage distinguishing the on-state of a transistor from an off-state of a transistor. This voltage Vₜₕ may further be a function of a voltage drop V_{BB}, this voltage may be defined as the difference between a source voltage V_{S} and a back-gate bias V_{BG}

V_{BB}=V_{S}−V_{BG} (1)

wherein the source voltage V_{S} may correspond to V_{L} or V_{R}. A linear approximation of Vₜₕ may be the given by

Vₜₕ=Vₜₕ⁰+αV_{BB} (2)

with an offset Vₜₕ⁰≧0 and a linear coefficient α>0. Eq. (2) illustrates that increasing the voltage drop V_{BB} may also increase the threshold voltage Vₜₕ. Since an increased Vₜₕ translates into a higher gate voltage V_{G} to be applied in order to set a transistor into its on-state, it may be advantageous to keep Vₜₕ at a minimum. Applying an appropriate back gate bias V_{BB} may completely open the conductive channel of the selection transistor 312 and less energy may be lost within the transistor 312, usually being dissipated as heat.

According to one embodiment of the present invention, a back-gate bias V_{BG}=V₄ is applied at point 316. The voltage V₄ is both a voltage easily available within the circuit and less than V_{S} or equal to V_{S}. Voltages being easily available within a circuit, such as an integrated circuit or memory device, are voltages which do not require additional voltage dividers and/or voltage generators, such as step-up converters or charge pumps. In the case of this embodiment, a voltage of 0 volts corresponds to a closest match satisfying both conditions. With V_{S} corresponding to V_{L} or to V_{R}, hence being in the range between 0.5 volt and 1.0 volt, and V₄ being approximately 0 volt, the voltage drop V_{BB} calculates from Eq. (1) as being in the range of 0.5 volt to 1.0 volt.

FIG. 3B illustrates a schematic view of a selection transistor 312 with a resistive memory element 319 according to a fourth embodiment of the present invention. According to this embodiment, the resistive memory element 319, such as the element 11 as described in conjunction with FIG. 1 or 2, is in a high-resistive state. During a program operation, a first voltage V₁ is applied at point 310, whereas a reference voltage, being lower than the first voltage V₁, is applied at the reference electrode 314. According to this embodiment, the first voltage V₁ may be approximately 0 volts, whereas the reference electrode 314 is at a voltage of approximately 1.5 volts.

In order to render the selection transistor 312 conductive, a gate voltage V_{G} is applied at point 317, being approximately 3 volts. There may be an effective resistance 311, for example the resistance of a bit-line, between the point 310 and the point 320 (V_{L}) at the selection transistor 312. The resistance 311 results in a voltage drop |V₁-V_{L}| between the point 310 and the point 320. Furthermore, the selection transistor 312 may also possess an effective resistance, which may result in a voltage drop |V_{L}-V_{R}| between the point 320 and the point 321. In the case of the resistive memory element 319 being in a high-resistive state, for example above 10 kΩ up to 1 GΩ and above, the resulting voltages may be approximately 0 volts for V_{L} and approximately 0 volt for V_{R}, due to the high resistance of the element 319.

According to one embodiment of the present invention, a back-gate bias V_{BG}=V₄ is applied at point 316. In the case of this embodiment, a voltage of 0 volts corresponds to a closest match satisfying the requirements of an easy availability and of being less than V_{S} or equal to V_{S}. With V_{S} corresponding to V_{L} or to V_{R}, hence being approximately 0 volt, and V₄ being approximately 0 volt, the voltage drop V_{BB} calculates from Eq. (1) as being approximately 0 volts, too. This may correspond to an almost ideal situation, since Vₜₕ, as may be calculated from Eq. (2), is minimized.

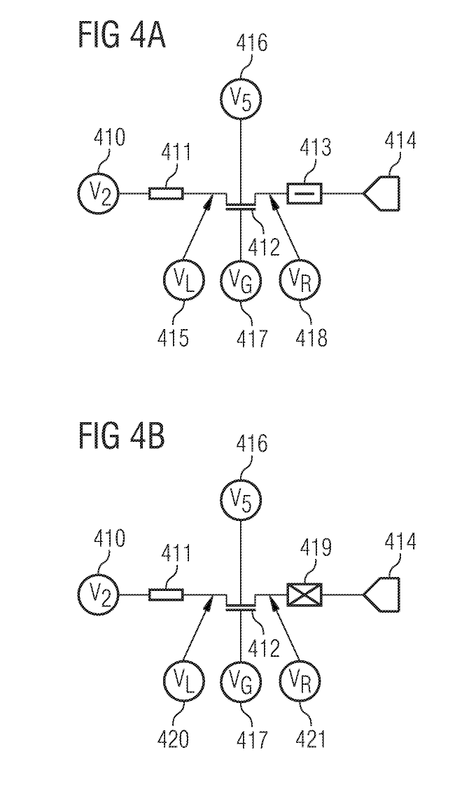

FIG. 4A illustrates a schematic view of a selection transistor 412 with a resistive memory element 413 according to a fifth embodiment of the present invention. According to this embodiment, the resistive memory element 413, such as the element 11 as described in conjunction with FIG. 1 or 2, is in a low-resistive state. During an erase operation, a second voltage V₂ is applied at point 410, whereas a reference voltage, being lower than the second voltage V₂, is applied at the reference electrode 414. According to this embodiment, the second voltage V₂ may be approximately 2.7 volts, whereas the reference electrode 414 is at a voltage of approximately 1.5 volts.

In order to render the selection transistor 412 conductive, a gate voltage V_{G} is applied at point 417, being approximately 3 volts. There may be an effective resistance 411, for example the resistance of a bit-line, between the point 410 and the point 415 (V_{L}) at the selection transistor 412. The resistance 411 results in a voltage drop |V₂-V_{L}| between the point 410 and the point 415. Furthermore, the selection transistor 412 may also possess an effective resistance, which may result in a voltage drop |V_{L}-V_{R}| between the point 415 and the point 418. In the case of the resistive memory element 413 being in a low-resistive state, for example below 10 kΩ, the resulting voltages may be approximately 2.3 volts for V_{L} and approximately 1.9 volt for V_{R}.

According to one embodiment of the present invention, a back-gate bias V_{BG}=V₅ is applied at point 416. The voltage V₅ is both a voltage easily available within the circuit and less than V_{S} or equal to V_{S}. In the case of this embodiment, a voltage of 1.5 volt corresponds to a closest match satisfying both conditions. With V_{S} corresponding to V_{L} or to V_{R}, hence being in the range between 1.9 volt and 2.3 volt, and V₅ being approximately 1.5 volt, the voltage drop V_{BB} calculates from Eq. (1) as being in the range of 0.4 volt to 0.8 volt. Compared to no application of a back gate bias, the threshold voltage Vₜₕ is hence decreased, which may affect the conductivity of the selection transistor 412 and may enable a reliable setting of the transistor into its on-state.

FIG. 4B illustrates a schematic view of a selection transistor 412 with a resistive memory element 419 according to a sixth embodiment of the present invention. According to this embodiment, the resistive memory element 419, such as the element 11 as described in conjunction with FIG. 1 or 2, is in a high-resistive state. During an erase operation, a second voltage V₂ is applied at point 410, whereas a reference voltage, being lower than the second voltage V₂, is applied at the reference electrode 414. According to this embodiment, the second voltage V₂ may be approximately 2.7 volts, whereas the reference electrode 414 is at a voltage of approximately 1.5 volts.

In order to render the selection transistor 412 conductive, a gate voltage V_{G} is applied at point 417, being approximately 3 volts. There may be an effective resistance 411, for example the resistance of a bit-line, between the point 410 and the point 420 (V_{L}) at the selection transistor 412. The resistance 411 results in a voltage drop |V₂-V_{L}| between the point 410 and the point 420. Furthermore, the selection transistor 412 may also possess an effective resistance, which may result in a voltage drop | V_{L}-V_{R}| between the point 420 and the point 421. In the case of the resistive memory element 419 being in a high-resistive state, for example above 10 kΩ up to 1 GΩ, the resulting voltages may be approximately 2.7 volts for V_{L} and approximately 2.7 volts for V_{R}, due to the high resistance of the element 419.

According to one embodiment of the present invention, a back-gate bias V_{BG}=V₅ is applied at point 416. The voltage V₅ is both a voltage easily available within the circuit and less than V_{S} or equal to V_{S}. In the case of this embodiment, a voltage of 1.5 volt corresponds to a closest match satisfying both conditions. With V_{S} corresponding to V_{L} or to V_{R}, hence being approximately 2.7 volt, and V₅ being approximately 1.5 volt, the voltage drop V_{BB} calculates from Eq. (1) as being approximately 1.2 volt. Compared to no application of a back gate bias, the threshold voltage Vₜₕ is hence decreased, which may affect the conductivity of the selection transistor 412 and may enable a reliable setting of the transistor into its on-state.

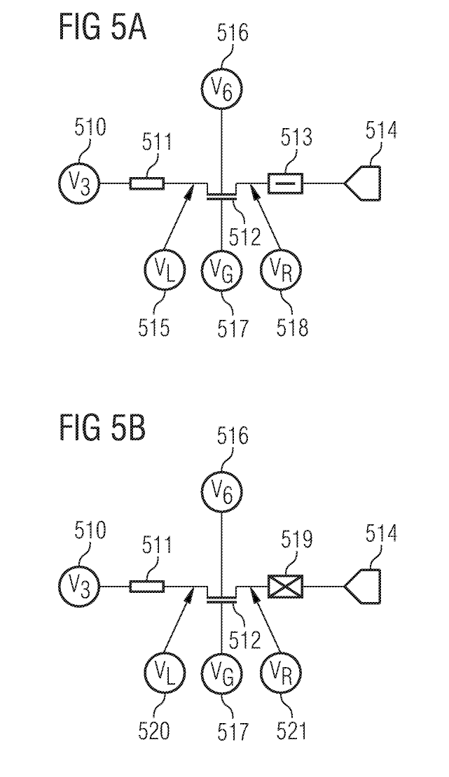

FIG. 5A illustrates a schematic view of a selection transistor 512 with a resistive memory element 513 according to a seventh embodiment of the present invention. According to one embodiment, the resistive memory element 513, such as the element 11 as described in conjunction with FIG. 1 or 2, is in a low-resistive state. During a read operation, a third voltage V₃ is applied at point 510, whereas a reference voltage, being higher than the third voltage V₃, is applied at the reference electrode 514. According to this embodiment, the third voltage V₃ may be approximately 1.2 volts, whereas the reference electrode 514 is at a voltage of approximately 1.5 volts. During a read operation, the absolute voltage drop between V₃ and the reference voltage may be less as for the case of a program operation or an erase operation. Although there may be a preferred direction of a resulting read current during a read operation, dependent on the type of resistive memory element used, the third voltage V₃ may also be higher than the reference voltage at the reference electrode 514. An example, which still satisfies a sufficiently low absolute voltage drop, may be a voltage of approximately 1.8 volts for V₃, whereas the voltage of 1.5 volts at the reference electrode may be maintained.

In order to render the selection transistor 512 conductive, a gate voltage V_{G} is applied at point 517, being approximately 3 volts. There may be an effective resistance 511, for example the resistance of a bit-line, between the point 510 and the point 515 (V_{L}) at the selection transistor 512. The resistance 511 results in a voltage drop |V₃-V_{L}| between the point 510 and the point 515. Furthermore, the selection transistor 512 may also possess an effective resistance, which may result in a voltage drop |V_{L}-V_{R}| between the point 515 and the point 518. In the case of the resistive memory element 513 being in a low-resistive state, for example below 10 kΩ, the resulting voltages may be approximately 1.3 volts for V_{L} and approximately 1.4 volts for V_{R}.

According to one embodiment of the present invention, a back-gate bias V_{BG}=V₆ is applied at point 516. The voltage V₆ is both a voltage easily available within the circuit and less than V_{S} or equal to V_{S}. In the case of this embodiment, a voltage of 1.2 volt corresponds to a closest match satisfying both conditions. With V_{S} corresponding to V_{L} or to V_{R}, hence being in the range between 1.3 volt and 1.4 volt, and V₆ being approximately 1.2 volt, the voltage drop V_{BB} calculates from Eq. (1) as being in the range of 0.1 volt to 0.2 volt. Compared to no application of a back gate bias, the threshold voltage Vₜₕ is hence decreased, which may affect the conductivity of the selection transistor 512 and may enable a reliable setting of the transistor into its on-state.

FIG. 5B illustrates a schematic view of a selection transistor 512 with a resistive memory element 519 according to an eighth embodiment of the present invention. According to this embodiment, the resistive memory element 519, such as the element 11 as described in conjunction with FIG. 1 or 2, is in a high-resistive state. During a read operation, a third voltage V₃ is applied at point 510, whereas a reference voltage, being lower than the third voltage V₃, is applied at the reference electrode 514. According to this embodiment, the third voltage V₃ may be approximately 1.2 volts, whereas the reference electrode 514 is at a voltage of approximately 1.5 volts.

In order to render the selection transistor 512 conductive, a gate voltage V_{G} is applied at point 517, being approximately 3 volts. There may be an effective resistance 511, for example the resistance of a bit-line, between the point 510 and the point 520 (V_{L}) at the selection transistor 512. The resistance 511 results in a voltage drop |V₃-V_{L}| between the point 510 and the point 520. Furthermore, the selection transistor 512 may also possess an effective resistance, which may result in a voltage drop |V_{L}-V_{R}| between the point 520 and the point 521. In the case of the resistive memory element 519 being in a high-resistive state, for example above 10 kΩ up to 1 GΩ and above, the resulting voltages may be approximately 1.2 volts for V_{L} and approximately 1.2 volts for V_{R}, due to the high resistance of the element 519.

According to one embodiment of the present invention, a back-gate bias V_{BG}=V₆ is applied at point 516. The voltage V₆ is both a voltage easily available within the circuit and less than V_{S} or equal to V_{S}. In the case of this embodiment, a voltage of 1.2 volt corresponds to a closest match satisfying both conditions. With V_{S} corresponding to V_{L} or to V_{R}, hence being approximately 1.2 volt, and V₆ being approximately 1.2 volt, the voltage drop V_{BB} almost vanishes as being calculated from Eq. (1). This may correspond to an almost ideal situation, since Vₜₕ, as may be calculated from Eq. (2), is minimized.

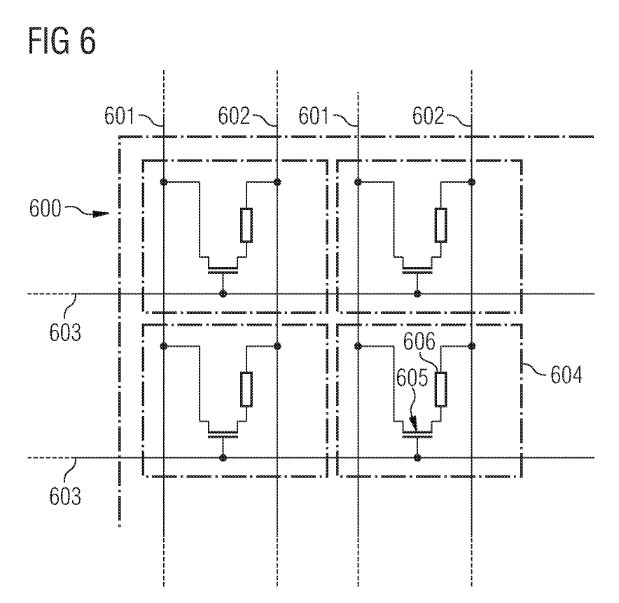

FIG. 6 illustrates a schematic view of an array of memory cells according to a ninth embodiment of the present invention. An array 600 of resistive memory cells 604 is illustrated in conjunction with bit-lines 601 and word-lines 603. The memory cells 604 are arranged in columns and rows along the bit-lines 601 and the word-lines 603, respectively. A memory cell 604 includes a selection transistor 605 and a resistive memory element 606. A specific memory cell 604 is selected by a respective addressing of the respective bit-line 601 and the respective word-line 603. The resistive memory elements 606 may be resistive elements such as the element 11, as described in conjunction with FIG. 1 or 2, and are coupled to the selection transistor 605 and to a reference line 602.

According to one embodiment of the present invention, one of the word lines 603 is set to a voltage such that the selection transistors 605, being coupled to the respective word line 603, become conductive, i.e. are put to their on-state. A first voltage or a second voltage is applied at one of the bit lines 601 to address a respective memory cell 604 at the crossing of the respective word line 603 and the respective bit line 601. The first voltage is applied to establish a first resistive state of the selected resistive memory element 606, while the second voltage is applied to establish a second resistive state of the selected resistive memory element 606.

The voltage at the reference line 602, i.e. the reference voltage, may be between the first voltage and the second voltage. In this way, the direction of the current through the resistive memory element 606 is reversed by switching the voltage of the bit line 601 between the first voltage and the second voltage. In the case of this bit line 601 being set to the first voltage, being higher than the second voltage and being higher than the reference voltage, a current flows from the bit line 601 through the selection transistor 605 and the resistive memory element 606 to the reference line 602. In the case that the bit line 601 is set to the second voltage, being lower than the first voltage and the reference voltage, a current flows from the reference line 602 through the resistive memory element 606 and the selection transistor 605 to the bit line 601.

Hence, it is possible, that the electronic current through the resistive memory element 601 is reversed by switching the bit line 601 between a first voltage and a second voltage, while keeping the selection transistor 605 in its on-state by a respective voltage at the word line 603. Since the reference electrode is tied to a voltage between the first voltage and the second voltage, wherein the second voltage may be as low as a ground potential, for example 0V, the potential of the bit line 601 need not to be drawn below the second voltage in order to achieve a bi-directional current. Generating a low voltage in an electronic circuit, particularly a voltage below a ground potential, may require additional components and may increase circuit complexity.

According to one embodiment of the present invention, the reference voltage on the reference line may be provided between 50 percent and 150 percent of a center voltage, the center voltage being equal to the second voltage plus half the difference between the first voltage and the second voltage. The reference voltage on the reference line may also be provided between 75 percent and 125 percent of the center voltage. The reference voltage on the reference line may furthermore correspond approximately to the center voltage. For example, the first voltage may correspond to a high-level voltage of 3 volts and the second voltage may correspond to a ground voltage of 0 volts, the center voltage accordingly being 1.5 volts.

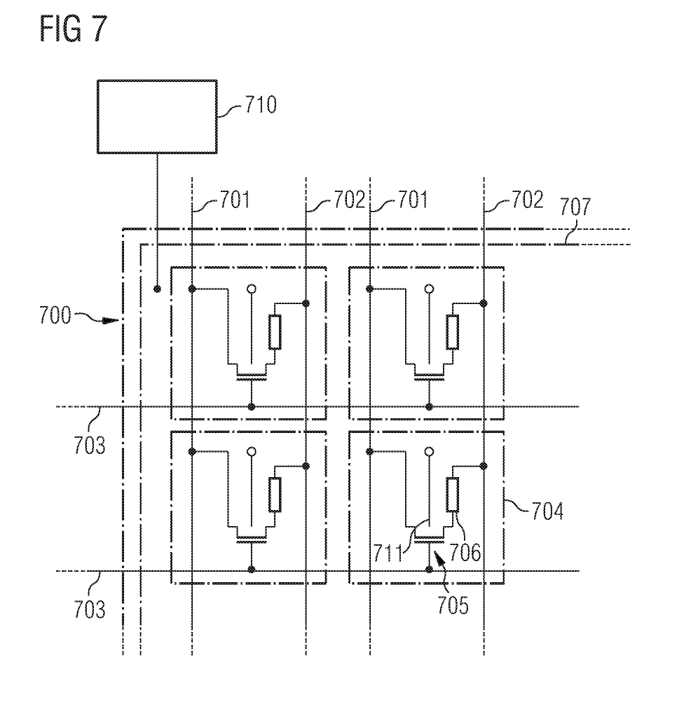

FIG. 7 illustrates a schematic view of an array of memory cells according to a tenth embodiment of the present invention. An array 700 of resistive memory cells 704 is illustrated in conjunction with bit-lines 701 and word-lines 703. The memory cells 704 are arranged in columns and rows along the bit-lines 701 and the word-lines 703, respectively. A memory cell 704 includes a selection transistor 705 and a resistive memory element 706. A specific memory cell 704 is selected by a respective addressing of the respective bit-line 701 and the respective word-line 703. The resistive memory elements 706 may be resistive elements such as the element 11, as described in conjunction with FIG. 1 or 2, and are coupled to the selection transistor 705 and to a reference line 702. The selection transistors 705 include a back gates 711, which are coupled to a back gate electrode 707.

According to one embodiment of the present invention, one of the word lines 703 is set to a voltage such that the selection transistors 705, being coupled to the respective word line 703, become conductive, i.e. are put to their on-state. A first voltage or a second voltage is applied at one of the bit lines 701 to address a respective memory cell 704 at the crossing of the respective word line 703 and the respective bit line 701. The first voltage is applied to establish a first resistive state of the selected resistive memory element 706 during a program operation, while the second voltage is applied to establish a second resistive state of the selected resistive memory element 706 during an erase operation. The first resistive state may correspond to a low-resistive state and the second resistive state may correspond to a high-resistive state.

The voltage at reference line 702, i.e. the reference voltage, may be between the first voltage and the second voltage. In this way, the direction of the current through the resistive memory element 706 is reversed by switching the voltage of the bit line 701 between the first voltage and the second voltage.

In the case of this bit line 701 being set to the first voltage, being higher than the second voltage and being higher than the reference voltage, a current flows from the bit line 701 through the selection transistor 705 and the resistive memory element 706 to the reference line 702. In the case that the bit line 701 is set to the second voltage, being lower than the first voltage and the reference voltage, a current flows from the reference line 702 through the resistive memory element 706 and the selection transistor 705 to the bit line 701.

It is possible, that the electronic current through the resistive memory element 701 is reversed by switching the bit line 701 between a first voltage and a second voltage, while keeping the selection transistor 705 in its on-state by a respective voltage at the word line 703. Since the reference electrode is tied to a voltage between the first voltage and the second voltage, wherein the second voltage may be as low as a ground potential, for example 0V, the potential of the bit line 701 need not to be drawn below the second voltage in order to achieve a bi-directional current. Generating a low voltage in an electronic circuit, particularly a voltage below a ground potential, may require additional components and may increase circuit complexity.

According to one embodiment of the present invention, the reference voltage on the reference line may be provided between 50 percent and 150 percent of a center voltage, the center voltage being equal to the second voltage plus half the difference between the first voltage and the second voltage. The reference voltage on the reference line may also be provided between 75 percent and 125 percent of the center voltage. The reference voltage on the reference line may furthermore correspond approximately to the center voltage. For example, the first voltage may correspond to a high-level voltage of 3 volts and the second voltage may correspond to a ground voltage of 0 volts, the center voltage accordingly being 1.5 volts.

A third voltage at the bit line 701 may be applied during a read operation for determining the resistive state of the selected resistive memory element 706. The difference between the third voltage and the reference voltage does not suffice to substantially alter the resistive state of the memory element 706. Therefore, the element 706 may be read out non-destructively.

The back gate electrode 707 is coupled to a back gate driver unit 710. The back gate driver unit 710 sets the voltage on the back gate electrode 707 according to an operation mode, i.e. dependent whether a program operation, an erase operation, or a read operation is carried out. Since the potential of the bit lines 701 and/or the word lines 703 may depend on the operation mode, a threshold voltage of the transistors 705 may also vary dependent on the operation mode. To enhance or to deplete the conduction of the selection transistors 705 in each operation mode, i.e. programming, erasing, or reading, the back gate driver unit 710 accordingly sets the voltage of the back gate electrode 707, hence also the potential of the back gates 711, for each operation mode. Detailed examples for voltages are given in conjunction with the description of FIGS. 3A through 5B.

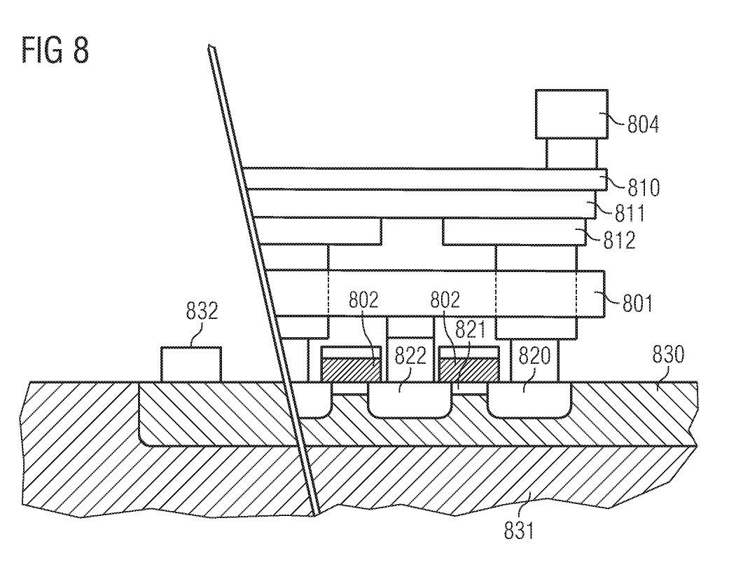

FIG. 8 illustrates a schematic cross-sectional view of a memory device with resistive memory cells, according to an eleventh embodiment of the present invention. According to this embodiment, an array of memory cells is structured on a substrate 831. The substrate 831 may be a p-doped silicon substrate and includes an isolated section 830 which is electrically isolated from the substrate 831, and may be set to a potential via a contact 832. The potential of the isolated section 830 may thus differ from the potential of the substrate 831, which may be a ground potential. The isolation of the substrate 831 from the isolated section 830 may be effected by a buried horizontal and/or vertical p-well. A first transistor terminal 820, a second transistor terminal 822, and a transistor channel 821 may be arranged being adjacent to the isolated section 830. The first terminal 820 and the second terminal 822 may be source/drain regions, such as doped regions of a semiconductor substrate. A word line 802 is arranged in vicinity of the transistor channel 821 and a bit line 801 is coupled to the second transistor terminal 822. The first transistor terminal 820 is coupled to a first electrode 812, and a second electrode 810 is coupled to a reference electrode 804. A programmable resistance layer 811 is arranged between the first electrode 812 and the second electrode 810.

The programmable resistance layer 811 changes its electric resistance by the application of electric signals, while the electric resistance remains stable in the absence of any signal. In this way, such a layer, or a fraction of such a layer, may store two or more logic states by a suitable programming of its electric resistance and hence represents a memory element. A binary coded memory element may, for example, store an information state “0” by assuming a high-resistive state, and an information state “1” by assuming a low-resistive state. In the case of the resistive memory cell being a magneto-resistive memory cell (MRAM) or a spin torque MRAM-cell, the cell may include a thin free magnetic layer, a thick fixed magnetic layer, and an intermediate isolating layer. In the case of the resistive memory cell being a phase change memory cell (PC-RAM), the cell may include a phase change material, which assumes different electric resistance states depending on its phase state. Furthermore, it may include a resistor or a heat element. In the case of the resistive memory cell being a conductive bridging memory cell (CB-RAM), the layer 811 may include a chalcogenide, such as GeSe, and a metal, such as Ag, or a calcogenice free material. Furthermore, one of the electrodes 810, 812 may include a material, such as Ag, which may form conductive bridgings in the layer 811.

Since the word line 802 may apply a voltage in the vicinity of the transistor channel 821 it may act as a gate and tune the electric conductivity of the channel 821. The isolated section 831 may be biased via a contact 832, and may act as a back-gate as described in conjunction with the preceding FIGS. 3A through 5B.

A program current, an erase current, or a read current may flow in both directions along a path of the bit line 801, the second transistor terminal 822, the transistor channel 821, the first transistor terminal 820, the first electrode 812, the programmable resistive layer 811, the second electrode 810, and the reference electrode 804. To enhance or to deplete the conduction of the transistor channel 821 in each operation mode, i.e. programming, erasing, or reading, the a back gate voltage may be applied at the substrate 831 accordingly for each operation mode. Detailed examples for voltages are given in conjunction with the description of FIGS. 3A through 5B.

Furthermore, the reference electrode 804 may be held at voltage which is between a first voltage of the bit line 801 and a second voltage of the bit line 801. Switching the voltage at the bit line 801 between the first voltage and the second voltage therefore reverses the direction of the current through the programmable resistive layer 811. Since the reference electrode is tied to a voltage between the first voltage and the second voltage, wherein the second voltage may be as low as a ground potential, for example 0V, the potential of the bit line 801 need not to be drawn below the second voltage in order to achieve a bi-directional current. Generating a low voltage in an electronic circuit, particularly a voltage below a ground potential, may require additional components and may increase circuit complexity.

In other embodiments, the selection transistors may be also replaced by selection devices. These selection devices may include, besides selection transistors, diodes, switches, n-channel field effect transistors, p-channel field effect transistors, bipolar transistors, or an SRAM cell. It should be noted that the above embodiments have been given in terms of an n-channel field effect transistor. However, the use of a p-channel transistor is alternatively possible, and included herein. In that case, the meaning of the “higher” and “lower” voltage levels will be interpreted accordingly.

In other embodiments, a memory cell may be arranged in an integrated circuit, such as a memory device, a memory module, a microprocessor, or a logic device. Therefore, an integrated circuit may be seen as a circuitry being realized in and on a single substrate or in and on more than one substrate. The integrated circuit may further provide packagings for the substrates and means for interconnection, such as chip carriers and/or printed circuit boards. Usually, a memory device includes one or more substrates with a plurality of memory cells each.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. An integrated circuit having a resistivity changing device, comprising:
a resistive element having a first resistive state and a second resistive state;
a selection device;
a conductive line, where the conductive line is configured to be set to a first voltage for establishing the first resistive state, and a second voltage for establishing the second resistive; and
a reference coupled to the resistive element, set to a voltage level between the first voltage and the second voltage.

2. The integrated circuit of claim 1, where the resistivity changing device is a resistive memory.

3. The integrated circuit of claim 1, where the resistivity changing device is configured to operate as a switch.

4. The integrated circuit of claim 1, comprising wherein the reference voltage level is provided between 50% and 150% of a center voltage, the center voltage being equal to the second voltage plus half the difference between the first voltage and the second voltage.

5. The integrated circuit of claim 1, comprising wherein the reference voltage level approximately corresponds to a center voltage, the center voltage being equal to the second voltage plus half the difference between the first voltage and the second voltage.

6. The integrated circuit of claim 1, comprising wherein the conductive line is set to a third voltage, the third voltage being provided between the first voltage and the second voltage, the third voltage being used to determine the state of the resistive memory element via the selection device having the on-state.

7. The integrated circuit of claim 1, wherein the selection device comprises a terminal coupled a an electrode set to a fourth voltage during the first resistive state set operation of the resistive element and to a fifth voltage during the second resistive state set operation of the resistive element.

8. A resistive memory cell comprising:
a resistive memory element, the resistive memory element having a first resistive state and a second resistive state;
a selection device, a first terminal of the selection device being coupled to a first terminal of the resistive memory element, the selection device having an on-state and an off-state;
a conductive line, the conductive line being coupled to a second terminal of the selection device, the conductive line being set to a first voltage, the first voltage establishing the first resistive state of the resistive memory element via the selection device having the on-state, the conductive line being set to a second voltage being lower than the first voltage, the second voltage establishing the second resistive state of the resistive memory element via the selection device having the on-state; and
a reference electrode, the reference electrode being coupled to a second terminal of the resistive memory element, the reference electrode being set to a voltage level being provided between the first voltage and the second voltage.

9. The memory cell as claimed in claim 8, comprising wherein the resistive memory element is any one of the group of a chalcogenide resistive element, a phase change resistive element and a spin torque resistive element.

10. The memory cell as claimed in claim 8, comprising wherein the reference electrode voltage level is provided between 50% and 150% of a center voltage, the center voltage being equal to the second voltage plus half the difference between the first voltage and the second voltage.

11. The memory cell as claimed in claim 8, comprising wherein the reference electrode voltage level is provided between 75% and 125% of a center voltage, the center voltage being equal to the second voltage plus half the difference between the first voltage and the second voltage.

12. The memory cell as claimed in claim 8, comprising wherein the reference electrode voltage approximately corresponds to a center voltage, the center voltage being equal to the second voltage plus half the difference between the first voltage and the second voltage.

13. The memory cell as claimed in claim 8, comprising wherein the conductive line is set to a third voltage, the third voltage being provided between the first voltage and the second voltage, the third voltage being used to determine the state of the resistive memory element via the selection device having the on-state.

14. The memory cell as claimed in claim 8, wherein the selection device comprises a third terminal, the third terminal being coupled to a second electrode, the second electrode being set to a fourth voltage during the first resistive state set operation of the resistive memory element and to a fifth voltage during the second resistive state set operation of the resistive memory element.

15. The memory cell as claimed in claim 14, comprising wherein the conductive line is set to a third voltage, being provided between the first voltage and the second voltage, the third voltage being used to determine the state of the resistive memory element via the selection device having the on-state, and wherein the second electrode is set to a sixth voltage during the state determining operation of the resistive memory element.

16. An integrated circuit comprising:
an array of resistive memory cells, the resistive memory cells comprising a resistive memory element and a selection device, the resistive memory element having a first resistive state and a second resistive state, a first terminal of the selection device being coupled to a first terminal of the resistive memory element, the selection device having an on-state and an off-state;
a bit line being coupled to a second terminal of the selection device, the bit line being set to a first voltage, the first voltage establishing the first resistive state of the resistive memory element via the selection device having the on-state, the bit line being set to a second voltage, the second voltage being lower than the first voltage, the second voltage establishing the second resistive state of the resistive memory element via the selection device having the on-state; and
a reference electrode, the reference electrode being coupled to a second terminal of the resistive memory element, the reference electrode being set to a voltage level being provided between the first voltage and the second voltage.

17. The integrated circuit as claimed in claim 16, comprising wherein the resistive memory element is any one of the group of a chalcogenide resistive element, a phase change resistive element and a spin torque resistive element.

18. The integrated circuit as claimed in claim 16, comprising wherein the reference electrode voltage level is provided between 50% and 150% of a center voltage, the center voltage being equal to the second voltage plus half the difference between the first voltage and the second voltage.

19. The integrated circuit as claimed in claim 16, comprising wherein the reference electrode voltage level is provided between 75% and 125% of a center voltage, the center voltage being equal to the second voltage plus half the difference between the first voltage and the second voltage.

20. The integrated circuit as claimed in claim 16, comprising wherein the reference electrode voltage approximately corresponds to a center voltage, the center voltage being equal to the second voltage plus half the difference between the first voltage and the second voltage.

21. The integrated circuit as claimed in claim 16, comprising wherein the bit line is set to a third voltage, the third voltage being provided between the first voltage and the second voltage, the third voltage being used to determine the state of the resistive memory element via the selection device having the on-state.

22. The integrated circuit as claimed in claim 16, wherein the selection device comprises a back gate terminal, the back gate terminal being coupled to a back gate electrode, the back gate electrode being set to a fourth voltage during the first resistive state set operation of the resistive memory element and to a fifth voltage during the second resistive state set operation of the resistive memory element.

23. The integrated circuit as claimed in claim 22, wherein the bit line is set to a third voltage, being provided between the first voltage and the second voltage, the third voltage being used to determine the state of the resistive memory element via the selection device having the on-state, and wherein the back gate electrode is set to a sixth voltage during the state determining operation of the resistive memory element.

24. A method of operating an integrated circuit having a resistive memory cell, comprising:
defining a resistive memory element, the resistive memory element having a first resistive state and a second resistive states; a selection device, a first terminal of the selection device being coupled to a first terminal of the resistive memory element, the selection device having an on-state and an off-state; a conductive line, the conductive line being coupled to a second terminal of the selection device; and a reference electrode, the reference electrode being coupled to a second terminal of the resistive memory element, comprising:
setting the selection device to the on-state;
setting the reference electrode to a voltage between a first voltage and a second voltage;
setting the conductive line to the first voltage, the first voltage establishing the first resistive state of the resistive memory element; and
setting the conductive line to the second voltage, the second voltage being lower than the first voltage and the second voltage establishing the second resistive state of the resistive memory element.

25. The method as claimed in claim 24, comprising wherein the resistive memory element is any one of the group of a chalcogenide resistive element, a phase change resistive element and a spin torque resistive element.

26. The method as claimed in claim 24, comprising wherein the reference electrode voltage level is provided between 50% and 150% of a center voltage, the center voltage being equal to the second voltage plus half the difference between the first voltage and the second voltage.

27. The method as claimed in claim 24, comprising wherein the reference electrode voltage level is provided between 75% and 125% of a center voltage, the center voltage being equal to the second voltage plus half the difference between the first voltage and the second voltage.

28. The method as claimed in claim 24, comprising wherein the reference electrode voltage approximately corresponds to a center voltage, the center voltage being equal to the second voltage plus half the difference between the first voltage and the second voltage.

29. The method as claimed in claim 24, wherein the method comprises setting the first conductive line to a third voltage, the third voltage being provided between the first voltage and the second voltage, to determine the state of the resistive memory element.

30. The method as claimed in claim 24, wherein the selection device comprises a third terminal, the third terminal being coupled to a second electrode, and wherein the method comprises:
setting the second electrode to a fourth voltage during the first resistive state set operation of the resistive memory element; and
setting the second electrode to a fifth voltage during the second resistive state set operation of the resistive memory element.

31. The method as claimed in claim 30, comprising:
setting the conductive line to a third voltage, the third voltage being provided between the first voltage and the second voltage, to determine the state of the resistive memory element; and
setting the second electrode to a sixth voltage during the state determining operation of the resistive memory element.

32. A resistive memory comprising:
a resistive memory element, the resistive memory element having a first resistive state and a second resistive state;
a selection device, a first terminal of the selection device being coupled to a first terminal of the resistive memory element, the selection device having an on-state and an off-state;
a conductive line, the conductive line being coupled to a second terminal of the selection device, the conductive line being set to a first voltage, the first voltage establishing the first resistive state of the resistive memory element via the selection device having the on-state, the conductive line being set to a second voltage being lower than the first voltage, the second voltage establishing the second resistive state of the resistive memory element via the selection device having the on-state;
a reference electrode, the reference electrode being coupled to a second terminal of the resistive memory element; and
a second electrode, the second electrode being coupled to a third terminal of the selection device, the second electrode being set to a third voltage during the first resistive state set operation of the resistive memory element and to a fourth voltage during the second resistive state set operation of the resistive memory element.

33. The memory as claimed in claim 32, comprising wherein the resistive memory element is any one of the group of a chalcogenide resistive element, a phase change resistive element and a spin torque resistive element.

34. The memory as claimed in claim 32, comprising wherein the conductive line is set to a fifth voltage, the fifth voltage being provided between the first voltage and the second voltage, the fifth voltage being used to determine the state of the resistive memory element via the selection device having the on-state.

35. The memory as claimed in claim 32, comprising wherein the conductive line is set to a fifth voltage, being provided between the first voltage and the second voltage, the fifth voltage being used to determine the state of the resistive memory element via the selection device having the on-state, and wherein the second electrode is set to a sixth voltage during the state determining operation of the resistive memory element.

36. The memory as claimed in claim 32, comprising wherein the reference electrode is set to a voltage level being provided between the first voltage and the second voltage.

37. The memory as claimed in claim 36, comprising wherein the reference electrode voltage level is provided between 50% and 150% of a center voltage, the center voltage being equal to the second voltage plus half the difference between the first voltage and the second voltage.

38. The memory as claimed in claim 36, comprising wherein the reference electrode voltage level is provided between 75% and 125% of a center voltage, the center voltage being equal to the second voltage plus half the difference between the first voltage and the second voltage.

39. The memory as claimed in claim 36, comprising wherein the reference electrode voltage approximately corresponds to a center voltage, the center voltage being equal to the second voltage plus half the difference between the first voltage and the second voltage.

40. An integrated circuit comprising:
an array of resistive memory cells, the resistive memory cells comprising a resistive memory element and a selection device, the resistive memory element having a first resistive state and a second resistive state, a first terminal of the selection device being coupled to a first terminal of the resistive memory element, the selection transistor having an on-state and an off-state;
a bit line being coupled to a second terminal of the selection device, the bit line being set to a first voltage, the first voltage establishing the first resistive state of the resistive memory element via the selection device having the on-state, the bit line being set to a second voltage, the second voltage being lower than the first voltage, the second voltage establishing the second resistive state of the resistive memory element via the selection device having the on-state;
a back gate electrode, the back gate electrode being coupled to a third terminal of the selection device, the back gate electrode being set to a third voltage during the first resistive state set operation of the resistive memory element and to a fourth voltage during the second resistive state set operation of the resistive memory element; and
a reference electrode, the reference electrode being coupled to a second terminal of the resistive memory element, the reference electrode being set to a voltage level being provided between the first voltage and the second voltage.

41. The integrated circuit as claimed in claim 40, comprising wherein the resistive memory element is any one of the group of a chalcogenide resistive element, a phase change resistive element and a spin torque resistive element.

42. The integrated circuit as claimed in claim 40, comprising wherein the bit line is set to a fifth voltage, the fifth voltage being provided between the first voltage and the second voltage, the fifth voltage being used to determine the state of the resistive memory element via the selection device having the on-state.

43. The integrated circuit as claimed in claim 40, comprising wherein the bit line is set to a fifth voltage, being provided between the first voltage and the second voltage, the fifth voltage being used to determine the state of the resistive memory element via the selection device having the on-state, and wherein the back gate electrode is set to a sixth voltage during the state determining operation of the resistive memory element.

44. The integrated circuit as claimed in claim 40, comprising wherein the reference electrode is set to a voltage level being provided between the first voltage and the second voltage.

45. The integrated circuit as claimed in claim 44, comprising wherein the reference electrode voltage level is provided between 50% and 150% of a center voltage, the center voltage being equal to the second voltage plus half the difference between the first voltage and the second voltage.

46. The integrated circuit as claimed in claim 44, comprising wherein the reference electrode voltage level is provided between 75% and 125% of a center voltage, the center voltage being equal to the second voltage plus half the difference between the first voltage and the second voltage.

47. The integrated circuit as claimed in claim 44, comprising wherein the reference electrode voltage approximately corresponds to a center voltage, the center voltage being equal to the second voltage plus half the difference between the first voltage and the second voltage.

48. A method of operating an integrated circuit having a resistive memory, comprising:
defining the resistive memory to include a resistive memory element, the resistive memory element having a first resistive state and a second resistive state; a selection device, a first terminal of the selection device being coupled to a first terminal of the resistive memory element, the selection device having an on-state and an off-state; a conductive line, the conductive line being coupled to a second terminal of the selection device; a reference electrode, the reference electrode being coupled to a second terminal of the resistive memory element; and a second electrode, the second electrode being coupled to a third terminal of the selection device, the method comprising:
setting the selection device to the on-state;
setting the reference electrode to a voltage between a first voltage and a second voltage;
setting the conductive line to the first voltage, the first voltage establishing the first resistive state of the resistive memory element;
setting the conductive line to the second voltage, the second voltage being lower than the first voltage and the second voltage establishing the second resistive state of the resistive memory element;
setting the second electrode to a third voltage during the first resistive state set operation of the resistive memory element; and
setting the second electrode to a fourth voltage during the second resistive state set operation of the resistive memory element.

49. The method as claimed in claim 48, comprising wherein the resistive memory element is any one of the group of a chalcogenide resistive element, a phase change resistive element and a spin torque resistive element.

50. The method as claimed in claim 48, wherein the method comprises the step of setting the conductive line to a fifth voltage, the fifth voltage being provided between the first voltage and the second voltage, to determine the state of the resistive memory element.

51. The method as claimed in claim 48, comprising:
setting the conductive line to a fifth voltage, the fifth voltage being provided between the first voltage and the second voltage, to determine the state of the resistive memory element; and
setting the second electrode to a sixth voltage during the state determining operation of the resistive memory element.

52. The method as claimed in claim 48, comprising wherein the reference electrode is set to a voltage level being provided between the first voltage and the second voltage.

53. The method as claimed in claim 52, comprising wherein the reference electrode voltage level is provided between 50% and 150% of a center voltage, the center voltage being equal to the second voltage plus half the difference between the first voltage and the second voltage.

54. The method as claimed in claim 52, comprising wherein the reference electrode voltage level is provided between 75% and 125% of a center voltage, the center voltage being equal to the second voltage plus half the difference between the first voltage and the second voltage.

55. The method as claimed in claim 52, comprising wherein the reference electrode voltage approximately corresponds to a center voltage, the center voltage being equal to the second voltage plus half the difference between the first voltage and the second voltage.
